(19) United States
(12) Patent Application Publication
(10) Pub. No.: US 2012/0266937 A1
(43) Pub. Date: Oct. 25, 2012

(54) DIFFRACTIVE OPTIC

(76) Inventors: Rajesh Menon, Salt Lake City, UT (US); Ganghun Kim, Salt Lake City, UT (US)

(21) Appl. No.: 13/274,903

(22) Filed: Oct. 17, 2011

Related U.S. Application Data
(60) Provisional application No. 61/393,668, filed on Oct. 15, 2010.

(51) Int. Cl. G02B 5/18; H01L 31/052; G01B 9/02

(52) U.S. Cl. 136/246; 359/575; 356/521

(57) ABSTRACT

A method for designing a diffractive optic includes identifying an initial performance metric for the diffractive optic, the diffractive optic including a substrate. A test cell is selected from an array of cells on the substrate. A height of the test cell is changed by a predetermined height unit. Images are computed at a plurality of discrete wavelengths or using a continuous spectrum using diffraction-based propagation through at least a portion of the array of cells. A wavelength metric is determined for each of the images. The wavelength metrics for each of the images is consolidated into a perturbed performance metric. The perturbed performance metric is compared to the initial performance metric and the method identifies whether the perturbed performance metric is an improvement over the initial performance metric.

### RELATED APPLICATION

This application claims the benefit of U.S. Provisional Application No. 61/393,668 entitled Diffractive Optic and Methods of Designing the Same, filed Oct. 15, 2010 and which is incorporated herein by reference.

### BACKGROUND

Diffractive optic elements are typically thin phase elements that operate by means of interference and diffraction to produce arbitrary distributions of light or to aid in the design of optical systems. For example, diffractive lenses can be used to reduce the number of elements in conventional lens systems and eliminate the use of exotic materials in correcting chromatic aberrations.

Diffractive optics sculpt the propagation of light to generate complex intensity and phase patterns downstream by imposing a phase and/or intensity pattern on the incident light. Phase-only diffractive optics affect the phase and are lossless. Binary-phase diffractive optics impose two-levels of phase, which significantly eases the fabrication of such elements. The phase shift is achieved via an optical-path difference between alternate zones. Such optics inherently exhibit chromatic aberrations. Generally, previous diffractive elements have been designed to operate optimally at a single wavelength, while efficiency and image contrast have been reduced at other wavelengths.

There have been various approaches to designing multiple-wavelength diffractive optics. One example includes a heterogeneous design based on materials with differing refractive indices and dispersion to compensate for chromatic aberration. By using phase shifts that are integer multiples of 2π, harmonic diffractive lenses can be designed for specific discrete wavelengths. However, the selection of the design wavelengths is limited. A nonlinear optimization technique has been used to design dual-wavelength diffractive beam-splitters. Blazed higher-order diffractive optics may also be designed for multiple wavelengths. In each of these cases, the fabrication of the diffractive optic is difficult due to the multiple levels of phase-height or due to large aspect ratios. Further, while the diffractive optics may operate at multiple wavelengths, the end result is a narrowband diffractive optic.

### SUMMARY

Diffractive optics, as well as systems and methods for designing such optics and systems and methods for using such optics are described.

A method for designing a diffractive optic is provided in accordance with an example of the present technology. The method includes identifying an initial performance metric for the diffractive optic. The performance metric may include optical efficiency, intensity uniformity, signal-to-noise ratio, etc. at each wavelength of interest. The diffractive optic can include a substrate. A test cell can be selected from an array of cells on the substrate. A height of the test cell can be changed by a predetermined height unit. Images can be computed at a plurality of discrete wavelengths using diffraction-based propagation through the array of cells. A wavelength metric can be determined for each of the images. The wavelength metrics for each of the images can be consolidated into a perturbed performance metric. The consolidation may be a simple summation, integration, addition with weighting factors, etc. The perturbed performance metric can be compared to the initial performance metric. The method can further include identifying whether the perturbed performance metric is an improvement over the initial performance metric.

A diffractive optic is described in accordance with an example of the present technology. The diffractive optic has a surface profile obtained by a process. The process includes identifying an initial performance metric for the diffractive optic, the diffractive optic including a substrate. A test cell is selected from an array of cells on the substrate. A height of the test cell is changed by a predetermined height unit. Images are computed at a plurality of discrete wavelengths using diffraction-based propagation through the array of cells. A wavelength metric is determined for each of the images. The wavelength metrics for each of the images is consolidated into a perturbed performance metric. The perturbed performance metric is compared to the initial performance metric and the method identifies whether the perturbed performance metric is an improvement over the initial performance metric.

A diffractive optic is described in accordance with another example of the present technology, which includes a substrate and an array of cells distributed on the substrate. The array of cells has a non-linear arrangement of cell heights extending from a surface of the substrate. The cell heights comprise preselected cell heights for a substantially optimized performance metric of the diffractive optic across a plurality of discrete wavelengths.

A system for designing a broadband diffractive optic is described in accordance with an example of the present technology. The system includes a performance module which identifies an initial performance metric for the diffractive optic including a substrate. A cell selection module selects a test cell from an array of cells on the substrate. A height modification module modifies a height of the test cell by a predetermined height. An image propagation module computes diffraction-based propagation of an image through the array of cells at a plurality of discrete wavelengths. A measurement module determines a wavelength metric for each of the images and consolidates the wavelength metrics for each of the images into a perturbed performance metric. A comparison module compares the perturbed performance metric to the initial performance metric. The performance module can be further adapted to identify whether the perturbed performance metric is an improvement over the initial performance metric and can assign the initial performance metric with a value of the perturbed performance metric when the perturbed performance metric is an improvement over the initial performance metric. Also, the operations performed by each of the system modules can collectively comprise cell processing.

### BRIEF DESCRIPTION OF THE DRAWINGS

FIG. 1 is a flow diagram of a method for designing a diffractive optic in accordance with an embodiment of the present technology;

FIG. 2 is a perspective view of a diffractive optic in accordance with an embodiment of the present technology;

FIG. 3 is a block diagram of a system for designing a diffractive optic in accordance with an embodiment of the present technology;

FIG. 4 is an iterative decision tree for designing a diffractive optic in accordance with an embodiment of the present technology;

FIG. 5 is a decision tree for designing a diffractive optic including block representations of a cells and cells heights of the diffractive optic in accordance with an embodiment of the present technology;

FIG. 6 includes graphics representing a solar cell concentrator system, electronic microscope scans of components of the solar cell concentrator system, and a graph of efficiencies for different regions of the solar cell concentrator system in accordance with an embodiment of the present technology; and

FIG. 7 includes graphics representing a linear solar cell concentrator system, electronic microscope scans of components of the solar cell concentrator system, and a graph of efficiencies for different regions of the solar cell concentrator system in accordance with an embodiment of the present technology.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

### DEFINITIONS

The following terminology will be used in accordance with the definitions set forth below.

As used herein, the singular forms “a,” and, “the” include plural referents unless the context clearly dictates otherwise.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of particles would either completely lack particles, or so nearly completely lack particles that the effect would be the same as if it completely lacked particles. In other words, a composition that is “substantially free of an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5,but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This principle also applies to ranges reciting only one numerical value as a minimum or a maximum. Furthermore, such an interpretation should apply regardless of the breadth of the range or the characteristics being described.

Reference will now be made to the exemplary embodiments illustrated, and specific language will be used herein to describe the same. It will nevertheless be understood that no limitation of the scope of the technology is thereby intended. Additional features and advantages of the technology will be apparent from the detailed description which follows, taken in conjunction with the accompanying drawings, which together illustrate, by way of example, features of the technology.

With the general examples set forth in the Summary above, it is noted in the present disclosure that when describing the system, or the related devices or methods, individual or separate descriptions are considered applicable to one other, whether or not explicitly discussed in the context of a particular example or embodiment. For example, in discussing the diffractive optic designs per se, the device, system, and/or method embodiments are also included in such discussions, and vice versa.

Furthermore, various modifications and combinations can be derived from the present disclosure and illustrations, and as such, the associated figures should not be considered limiting.

Further details regarding diffractive optics and the use of the same in solar cells is found in US patent publication numbers 2010/0095999 and 2010/0097703, both of which are incorporated herein by reference in their entirety. Additional details regarding diffractive optic fabrication techniques are found in: D. Gil, R. Menon & H. I. Smith, Microelectron. Eng. V. 73-74, 35-41 (2004); and M. D. Galus, E. E. Moon, H. I. Smith & R. Menon, J. Vac. Sci. Technol. B 24(6), 2960-2963 (2006); both of which are incorporated herein by reference in their entirety.

Diffractive optics, as well as systems and methods for designing such optics and systems and methods for using such optics are described herein. More specifically, high efficiency diffractive optical elements that will operate over a large wavelength range, as well as the design and use of the same, are described. In some examples, high-efficiency light concentrators that select the solar spectrum and achieve high-energy conversion efficiency can be designed and produced will be described. However, these examples are intended to be non-limiting and the technology may be used in virtually any application in which a multi-wavelength diffractive optic is desired.

In general, iterative optimization techniques can be used to design diffractive optics at single wavelengths (or for narrowband illumination) as has been described. For multiple wavelengths, however, the design process is non-trivial since diffractive optics are generally highly wavelength-sensitive. Furthermore, material dispersion over large spectral ranges also affects the design of such optics.

Previous iterative approaches, such as the classical Gerchberg-Saxton algorithm and modified error-reduction methods, do not work to produce diffractive optics operable with broadband illumination. This is because the relationship between phase and the optic height is both wavelength and material dependent. In other words, there is not a one-to-one relationship between the phase and the optic-height when designing diffractive optics operable with broadband illumination, which relationship is used in conventional iterative design methods. An alternative iterative approach to designing diffractive optics operable with broadband illumination is described below.

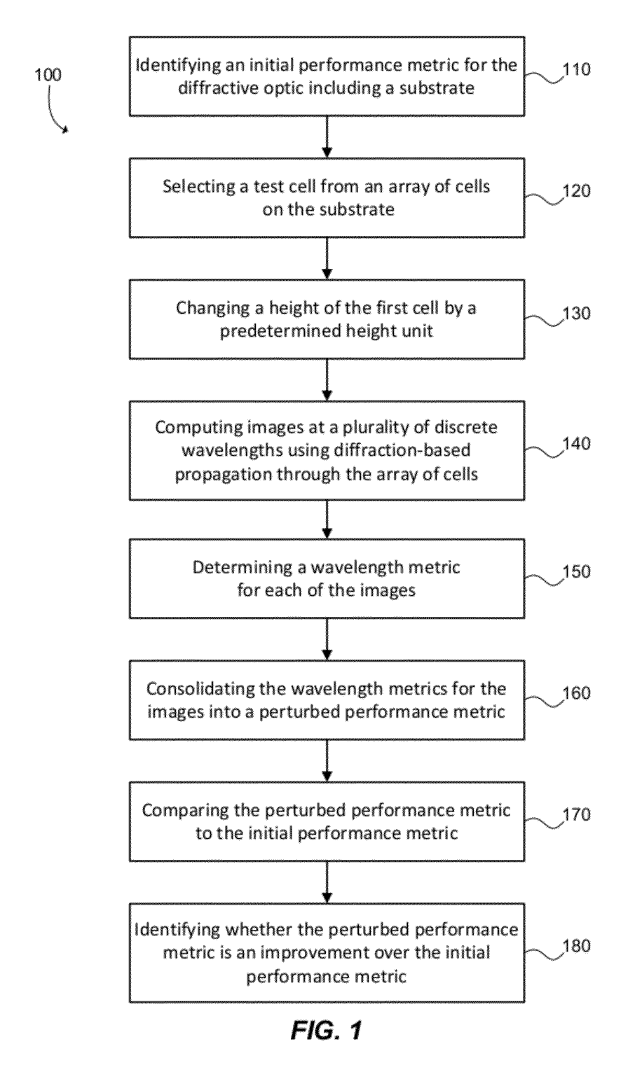

An Iterative Pixelated Perturbation Method (IPPM) can be used to design a diffractive optic. Referring to FIG. 1, a flow diagram of the method 100 is shown. The method includes identifying 110 an initial performance metric for the diffractive optic, the diffractive optic including a substrate. The diffractive optic may operate in transmission or in reflection. A test cell is selected 120 from an array of cells on the substrate. The array of cells can include any desired number of cells. For example, the array may comprise a matrix of 1,000×1,000 cells, 25,000×25,000 cells, etc. The size of the array can vary depending on the application and can vary from hundreds across to tens of thousands across, or more. Further, although symmetric arrays are listed, non-symmetric arrays (i.e. different numbers of x and y cells) can also be optimized using these methods. Note that each cell can also be non-symmetric, i.e., although square cells are illustrated, the cell can be a rectangle, a circle, a ring (in the case of radially symmetric designs) and any other shape that can tile a two-dimensional (2D) surface. Also, rectangles can be used, for instance, in one-dimensional (1D) designs. With a 1D solar concentrator, tracking the sun every day can be avoided. Also, it is easier to design and fabricate 1D optics. Each cell can comprise an area on the substrate of a few nanometers to tens of nanometers. The cells can also be larger or smaller and may be limited simply by the manufacturing method used.

A height of the test cell can be changed 130 by a predetermined height unit. A height unit can be any desired height. For example, a cell height can be increased or decreased by one nanometer, or by ten nanometers, or any other desired increment. Although increments can be varied, as a general guideline the increment can be from about 2-50 nm and in some specific cases may be less than 5 nm. However, increment values larger than 50 nm can be suitable for some applications. Choice of this value can be a function of equipment resolution limitations and design specifications (i.e. a higher target efficiency can benefit from smaller increments). Further, the method 100 may be adjusted to provide a variable increment adjustment from pixel-to-pixel or along a repeated iteration across the array. For example, a first iteration across the array could use a 30 nm increment while a second iteration could use a 10 nm increment.

Images can be computed 140 at a plurality of discrete wavelengths using diffraction-based propagation through the array of cells. This propagation can be done assuming a continuous spectrum. In other words, this method is not restricted to discrete wavelengths. The mathematics will be different for a continuous spectrum as compared with discrete wavelengths but the method is still the same. In the continuous spectrum case, properties of the source can be taken into consideration, such as spatial and temporal coherence. The substrate can be fabricated and tested for each cell change, but this may be cost-prohibitive. As a result, a computer, or grid of computers can be used to compute propagation of light or images through the array of cells. In one example, the images propagated through the array of cells can include one or more specific wavelengths of light, or ranges of wavelengths or sets of discrete wavelengths. Use of multiple images can be useful in testing various metrics related to the propagation of light through the array of cells.

In an example including discrete wavelengths, the plurality of discrete wavelengths can span a broadband or narrow band spectral field. For example, narrow band optics can be optimized for specific color ranges, visible light, UV (ultraviolet) light, IR (infrared) light (including near-infrared light), and the like. Furthermore, the diffractive optic can be broadband. In addition, the diffractive optic can be a hybrid refractive-diffractive optic.

A wavelength metric can be determined 150 for each of the images propagated through the array of cells. Although spectral efficiency is one useful metric, other metrics can be used alone or in combination with spectral efficiency, such as, but not limited to, image quality, spatial coherence, temporal coherence, and the like. These metrics can optionally be weighted when used in combination.

The wavelength metric(s) for each of the images is consolidated 160 into a perturbed performance metric. The perturbed performance metric is a performance metric which is altered due to the change in height of one or more of the cells, the performance metric being changed as a result of the change in height from an original or previous performance metric to a perturbed performance metric. The perturbed performance metric is compared 170 to the initial performance metric and the method identifies 180 whether the perturbed performance metric is an improvement over the initial performance metric.

The method can further include assigning the initial performance metric the value of the perturbed performance metric when the perturbed performance metric is an improvement over the initial performance metric. The method can further include discarding perturbed performance metric when the perturbed performance metric is not an improvement over the initial performance metric. The method can also further include repeating the method for each cell in the array at least once. Alternatively, the steps of the method can be repeated for only a portion of the cells in the array (i.e. at least 80% or more). In general, enough cells can be optimized to provide for a desired increase or level of optimization of the configuration.

In further examples, the test cell is selected randomly from the array of cells, or alternately is selected from the array of cells according to a predetermined selection pattern. Changing the height of the first cell by the predetermined height unit can include increasing or decreasing the height by the predetermined height unit. Also, examples of the wavelength metric include propagation efficiency of at least one of the images through the array of cells and image uniformity measured after at least one of the images is propagated through the array of cells.

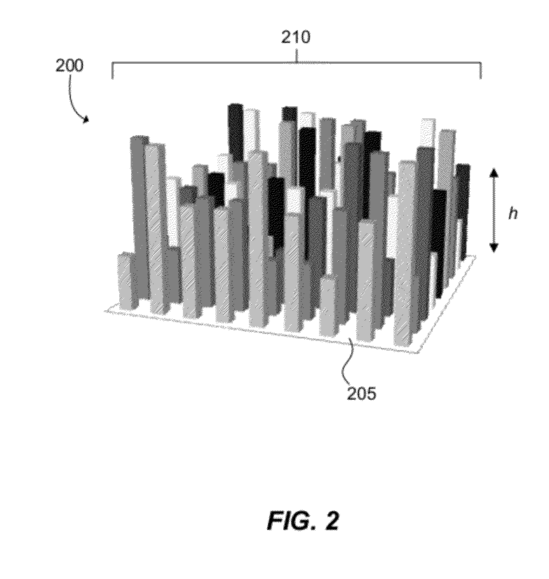

Referring to FIG. 2, a perspective view of a broadband diffractive optic 200 is shown in accordance with an embodiment of the present technology. The broadband diffractive optic includes a substrate 205 and an array of cells 210 distributed on the substrate. The array of cells has a non-linear arrangement of cell heights extending from a surface of the substrate. The cell heights comprise preselected cell heights h for a substantially optimized performance metric of the broadband diffractive optic across a plurality of discrete wavelengths.

The array of cells 210 can have a non-linear arrangement of cell heights extending from a surface of the substrate. The cell heights comprise preselected cell heights for a substantially optimized performance metric of the diffractive optic across a plurality of discrete wavelengths. The degree of optimization can vary from specific application and configuration but can most often be from about 20% to about 99% efficiency. For example, in broadband applications an optimized performance metric can obtain an efficiency from about 20% to about 30%, while an optimized narrow band configuration such as IR band may have an efficiency from about 80% to about 95%. Achievable spectral efficiencies can vary depending on the spectral bandwidth, image geometry, and the like. However, generally, optics can be obtained which are 7-9 times more efficient than conventional approaches. Such dramatically optimized configurations can allow efficiencies for solar cells, LEDs, and other applications (e.g. color mixing and separation as described in U.S. Provisional Application No. N/A, entitled “Ultra-High Efficiency Color Mixing and Color Separation,” filed Sep. 27, 2010 which is incorporated herein by reference) to provide for reduced energy losses and increased performance. As used herein, the term “optimized” refers to a configuration which has been designed to achieve exceptionally high efficiencies which approach theoretical limits for the array type. For example, a conventional non-optimized broadband array may have a 1% or less efficiency while theoretical efficiencies can approach about 30%. An “optimized” configuration would be one that comes within 50% of a theoretical maximum, in some cases within about 70%, and often within about 90% of a theoretical maximum. As non-limiting examples, an optimized optic having efficiencies over about 30% may be obtained (e.g. with bandwidths over 300 nm). Spectral splitting can also result in high efficiencies.

In a more specific implementation, the diffractive optic is a component of a solar concentrator system. The solar concentrator system can include plurality of solar cells having different ranges of spectral band efficiencies. The diffractive optic can further comprise a plurality of regions, each region having cell heights arranged for increased efficiency for a different spectral band range. In some examples, the spectral band ranges for different regions may at least partially overlap. In some examples, some regions will have a same or similar spectral band range as compared with other regions on the substrate which will have an at least partially different spectral band range.

Each of the plurality of regions can have an increased efficiency for a specific spectral band range as compared with the efficiency for a same specific spectral band range at a different region arranged for a different spectral band range. The plurality of regions can be aligned with the plurality of solar cells such that a region arranged for a specific spectral band range is aligned with a solar cell designed for the specific spectral band range. This approach can be helpful to provide regionally optimized optics which cover relatively narrow spectral ranges rather than trying to optimize an entire array for a full spectrum. As a general rule, an array optimized over a full spectrum will have a lower overall efficiency that an array of the same size which is optimized over a narrower spectrum.

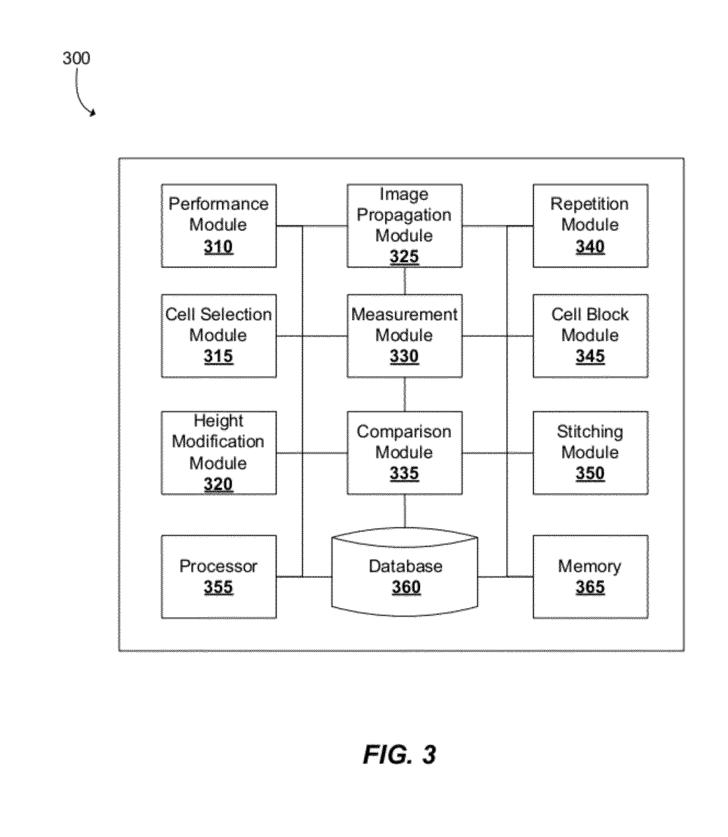

Referring to FIG. 3, a block diagram of a system 300 is shown for designing a broadband diffractive optic in accordance with an embodiment of the present technology. A performance module 310 identifies an initial performance metric for the diffractive optic including a substrate. A cell selection 315 module selects a test cell from an array of cells on the substrate. A height modification 320 module modifies a height of the test cell by a predetermined height. An image propagation module 325 computes diffraction-based propagation of an image through the array of cells at a plurality of discrete wavelengths. A measurement module 330 determines a wavelength metric for each of the images and consolidates the wavelength metrics for each of the images into a perturbed performance metric. A comparison module 335 compares the perturbed performance metric to the initial performance metric. The performance module can be further adapted to identify whether the perturbed performance metric is an improvement over the initial performance metric and can assign the initial performance metric with a value of the perturbed performance metric when the perturbed performance metric is an improvement over the initial performance metric. Also, the operations performed by each of the system modules can collectively comprise cell processing. These modules can be individually driven and operated by or in conjunction with logic and other devices such as, but not limited to, a processor 355, logic circuits, programmable logic devices, memory 365, and the like, and which include associated instructions in the form of software or hard-coded logic systems, which instructions in some examples may be loaded into the memory.

The system can also include a database 360 on a non-transitory computer readable storage medium for storing the height of the test cell and the initial performance metric. A plurality of computing nodes, such as servers, processors, and the like can be used for simultaneously or sequentially processing different test cells. A repetition module 340 can cause the performance module 310, the cell selection module 315, the height modification module 320, the image propagation module 325, the measurement module 330, and the comparison module 335 to operate to process each cell in the array of cells at least once. A cell block module 345 can be used for dividing the array of cells into overlapping blocks containing subsets of the cells in the array, wherein multiple overlapping blocks are processed simultaneously. Different computing nodes can calculate the heights or optimization for different blocks of cells. A stitching module 350 can stitch the blocks together to reform the array of cells after each cell in the array of cells, or rather after each block, is processed. The stitching module can match up discrepancies in cell heights where blocks overlap, for example, by selecting a point in between two different heights for a same cell, or by selecting the height for one of the cells.

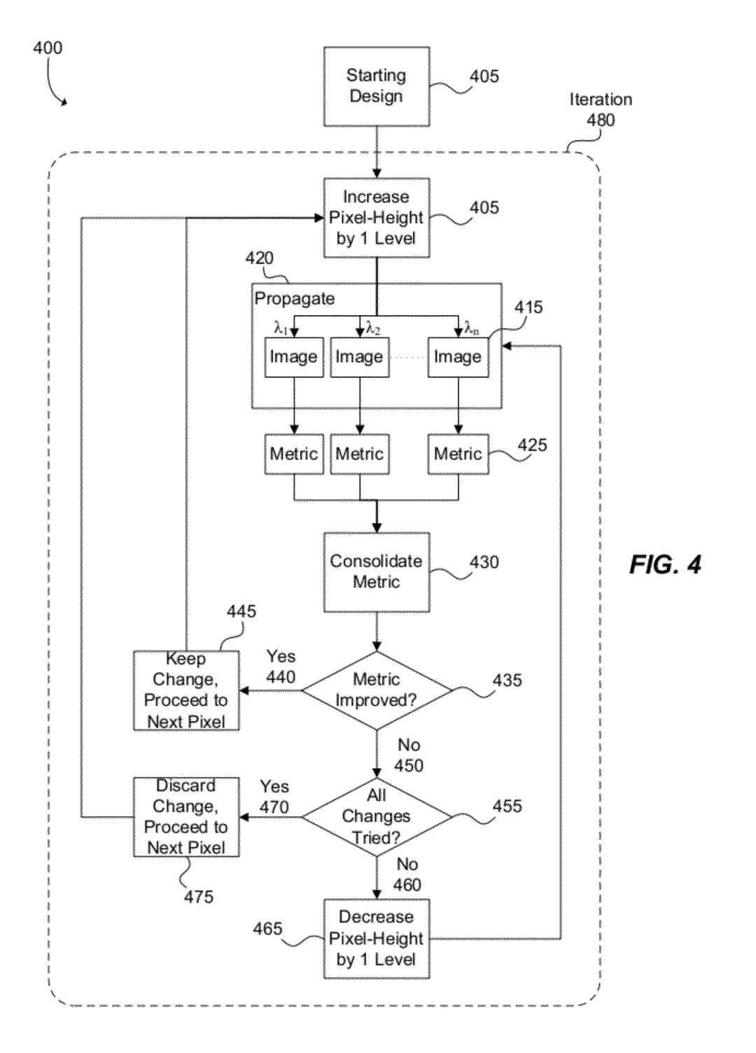

Referring to FIG. 4, an iterative decision tree 400 is illustrated for designing a broadband diffractive optic in accordance with an embodiment of the present technology. The broadband diffractive optic is represented as a matrix of height values. In an example case, the diffractive optic can be fabricated as a topographical (height) pattern on a transparent substrate, such as glass. Other substrates suitable for use in optical applications can also be used and are considered within the scope of this disclosure. An example fabrication approach includes lithography. Various lithographic methods can be used to fabricate a desired topographical pattern on the substrate.

The pixel-sizes and the discrete height levels are determined by the fabrication technology. The design method is based on a direct nonlinear optimization method. The iterative decision tree 400 illustrated in FIG. 4 begins with a starting design 405, which can be generated by a variety of means. For example, the design, or a starting point for the design, can be generated and/or selected using a modified-error reduction (MER) approach for a single wavelength. However, any other starting point could also be used. In this case, the following steps can be conducted:
1. The optic-height of the first pixel is perturbed by increasing 410 the height of the first pixel by a pre-defined unit-height, such as 5 nm, for example.
2. The images 415 at the various discrete wavelengths are computed using a simple diffraction-based propagation method 420 (such as an angular-plane wave spectrum method).
3. The figure-of-merit (or metric 425) for each of the images is computed. For example, this metric may include spectral efficiency or a combination of spectral efficiency and image uniformity.
4. The individual wavelength metrics are consolidated 430 into a single metric. For example, consolidation may be performed by computing a weighted average of the metric. An example result of the consolidation may be an average spectral efficiency.
5. The process queries 435 whether the consolidated metric is improved. If the consolidated metric is improved from the previous iteration (i.e., “Yes” 440), then the perturbation, or change in height of the pixel, is kept 445 and steps 1-5 are repeated with the next pixel. If the consolidated metric is not improved (i.e., “No” 450), then the process queries 455 whether all expected changes to the pixel height have been tried, such as decreasing or increasing the pixel height by the predetermined amount. If no 460, steps 1-5 may be repeated with the same pixel. However, in step 1, the optic-height is reduced 465 by the predetermined unit-height from original height before the increase in height. Alternatively, the pixel height may be further increased by an additional level or amount as compared with the initial increase. Finally, if perturbations of increasing or decreasing the height do not improved the metric (i.e., “Yes” 470 at “All Changes Tried?” 455), the perturbations are discarded 475 and steps 1-5 are repeated with the next pixel.

Once all pixels in a region of the array, or in the entire array, are considered, the iteration 480 or method can continue with the first pixel in the region or entire array again. The iteration can cease when all the pixels have been considered and there is no further change in the consolidated metric, or at least when the change in the consolidated metric is not greater than a predetermined threshold. The number of iterations is not specifically limited and may vary widely depending on the particular design, tolerance and specification. However, in one example, the number of iterations can be about 20-25. In one example, the direction of scan of the pixels may be changed to improve the results, such that each iteration processes the pixels in a different order or direction than a previous iteration. In one example, the pixels can be selected or processed randomly.

While reference has been made to cells in FIGS. 1-3 and pixels in FIG. 4, the terms can be synonymous. A cell or pixel can refer to a defined area on the substrate which is discrete and/or has a height which is independent of other adjacent or nearby cells or pixels. Although the height of a discrete cell or pixel is independent of other adjacent or nearby cells or pixels, the height of the discrete cell in some examples may be the same as the height of the other adjacent or nearby cells or pixels.

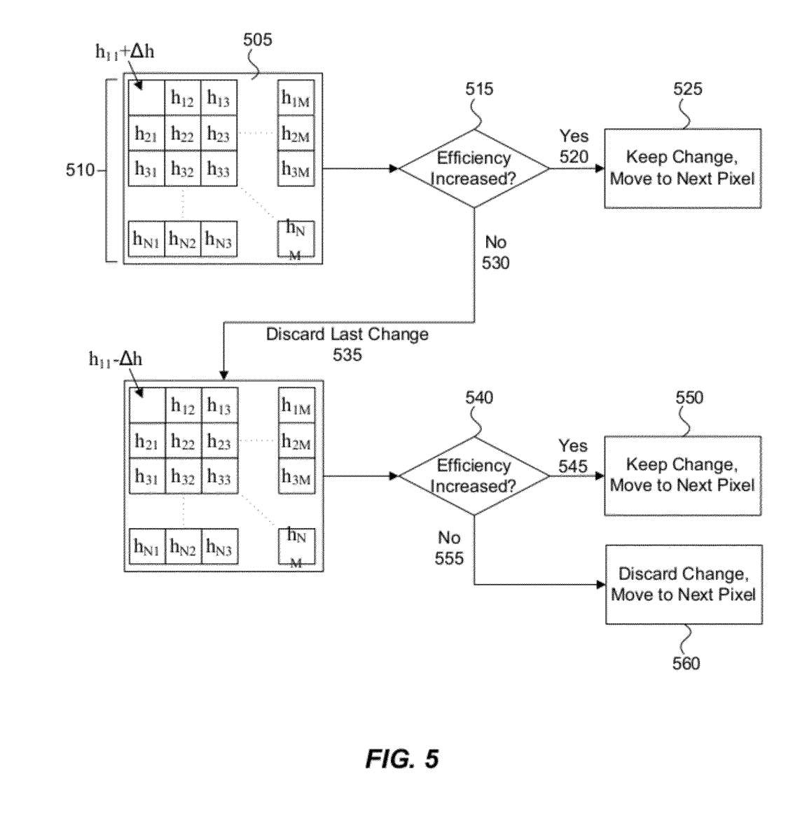

The details of the perturbation approach are further illustrated in FIG. 5. The process considers an array of pixels 510 (i.e., h₁₁-h_{NM}) on a substrate 505. In this example, the optic height at the top-left pixel h₁₁ is perturbed by adding an additional height Δh. In one example, the additional height may be selected based on fabrication constraints. Images at various wavelengths are computed and the effect on the consolidated metric, such as average spectral efficiency, is verified. If the metric is improved, this perturbation is kept, and the iteration moves on to the next pixel. If the metric is not improved, the previous perturbation is discarded. In illustrated example, the process queries whether efficiency has increased 515. If “Yes” 520, the changed pixel height of h₁₁ is kept 525 and the process moves on to the next pixel, such as h₁₂, for example. If “No” 530, the change in pixel height (i.e., the increase in the height of h₁₁) is discarded 535, and the the same pixel h₁₁ is further perturbed by decreasing the optic-height by Δh. Again, the images at the various wavelengths are computed and the effect on the consolidated metric, such as average spectral efficiency, is verified. Again the process queries 540 whether the metric is improved. If “Yes” 545, the perturbation is kept 550, and the iteration moves on to the next pixel. If the metric is not improved (i.e., “No” 555), the previous perturbation is discarded 560 and the iteration moves on to the next pixel as illustrated.

Some of the features of the described perturbation approach include the ability to consider real material dispersion parameters over an arbitrary spectral bandwidth in a computationally efficient manner. The approach also behaves well from a computational perspective. More specifically, fast fourier transform-based convolution, as well as fast perturbation theory-based approaches, can be used to compute the images. Also, the method is easily parallelized by configuring separate computing cores to compute images at different wavelengths. The method can be performed with little to no inter-core communication and computational overhead is low. The method is able to perform an exhaustive search (i.e., iterative processing of the pixels) because the method is not driven by a local phase-slope, as is the case in a classical simplex method. In addition, convergence is assured because the number of combinations of pixels and discrete height levels is limited. The method is also general enough to be usable for arbitrary spatial spectral image designs.

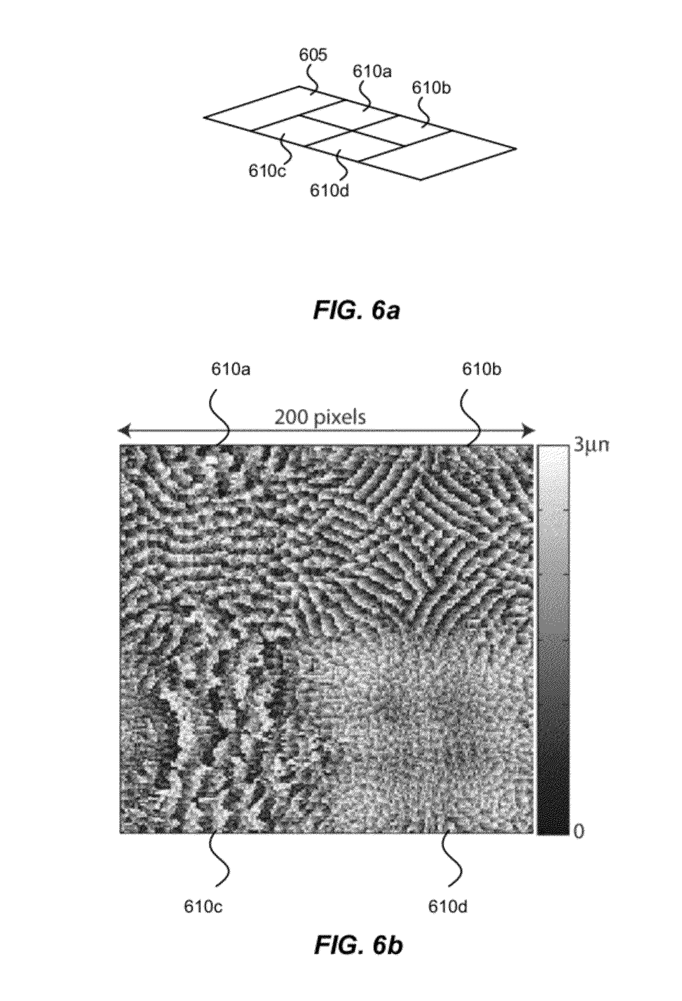

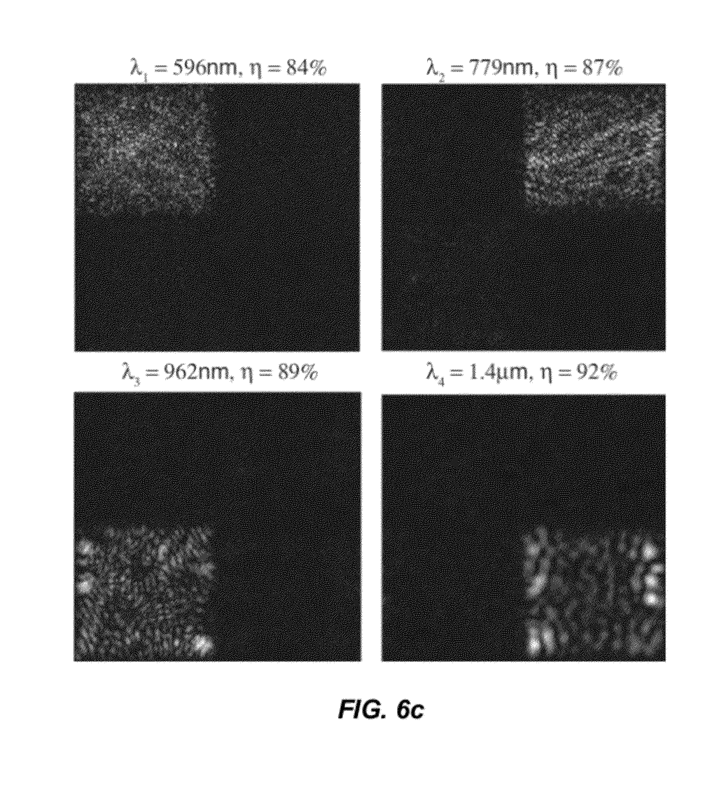

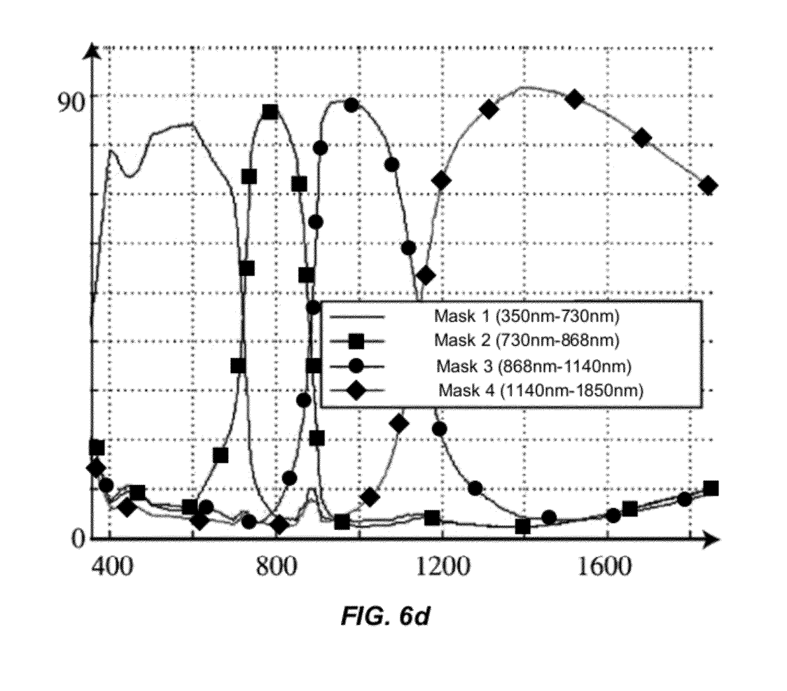

To demonstrate efficacy, the IPPM (Iterative Pixelated Perturbation Method) was used to design solar concentrators that not only concentrate sunlight but also separate the spectral bands. Because the spectral bands can be matched to appropriate solar cells, very high-efficiency solar-power generation can be achieved. FIGS. 6a-6c illustrate an example spectrum-splitter design for concentrating sunlight (350 nm to 1850 nm) into four spectral bands: 350-730 nm, 730-868 nm, 868-1140 nm and 1140-1850 nm. The spectral bands were assigned to four quadrants 610a-610d on an image plane 605, as shown in FIG. 6a. Four equal-area solar cells can be placed at these quadrants. When the band-gaps of these solar cells match the band-edges of the corresponding spectral bands, high-efficiency solar-power generation is enabled. The polychromat is the optic that assigns the four spectral bands to the laterally spaced solar cells.

FIG. 6b shows the calculated heights of the array of cells (the color scale bar should say 6 μm rather than 6 μm) of a completed diffractive optic design. The height map shows four differently organized regions 610a-610d designed for four different spectrums. FIG. 6c shows four images formed when four discrete wavelengths are incident on the polychromat to illustrate the performance. Each wavelength is chosen as a representative of a spectral band. FIG. 6c shows amplitude of the image at four discrete wavelengths to illustrate the light distribution on the solar cells. As can be appreciated, each of the regions produces an image for the wavelength spectral band for which the region was designed and not for the other bands.

FIG. 6d shows a spatial-spectral efficiency plot of the polychromat of FIGS. 6a-6b as a function of wavelength. As shown in FIG. 6d, the polychromat achieves high efficiencies over nearly the entire solar spectrum. The four spectral bands are assigned to the appropriate spatial locations with very high optical efficiencies.

Different materials can be used for the substrate to accommodate the different spectral ranges. For example, crystalline silicon may work well for wavelengths up to 1.1 microns. Amorphous silicon may work well for wavelengths above 1.1 microns. Different materials for solar cells with various bandgaps can be used. For diffractive optic, the cells are typically made of the same material. This material is usually a transparent plastic such as photoresist, polymethylmethacrylate (PMMA), or other polymer that are transparent to the wavelengths of interest. The material can also be easily fabricated into the multiple height levels. The material can also be glass, fused silica, silica, quartz, fused quartz, etc. The substrate can be PMMA, glass, fused silica, fused quartz, silica, quarts or any material that can provide a rigid support and also be transparent at the wavelengths of interest. Note that if the diffractive optics is used in reflection, the substrate is highly reflective at the wavelengths of interest instead of being transparent.

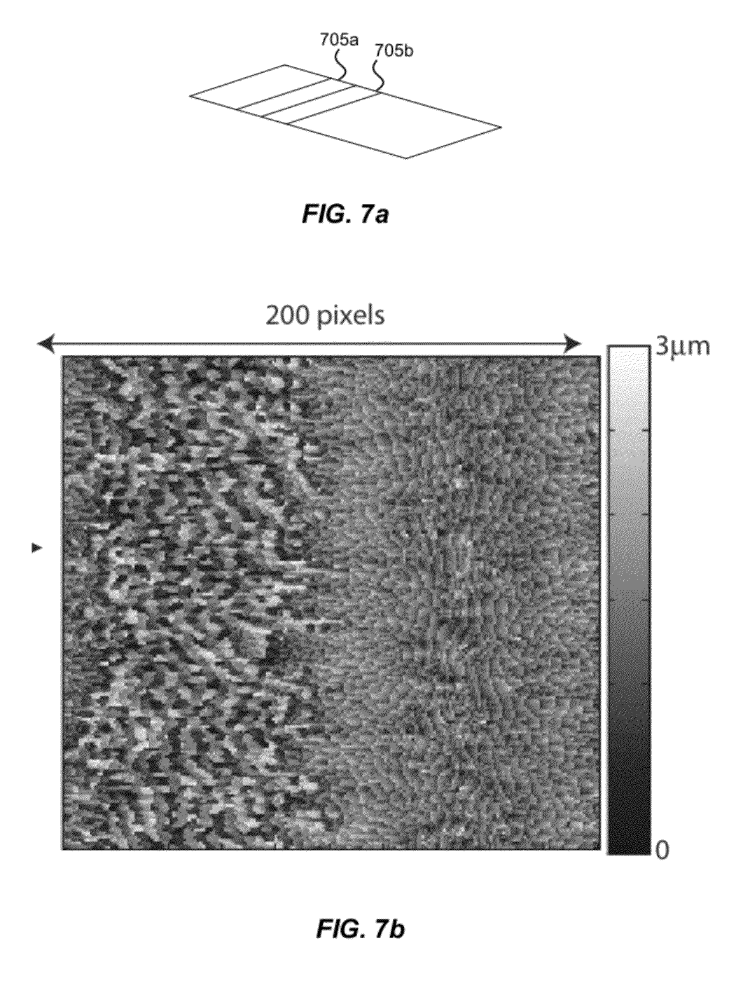

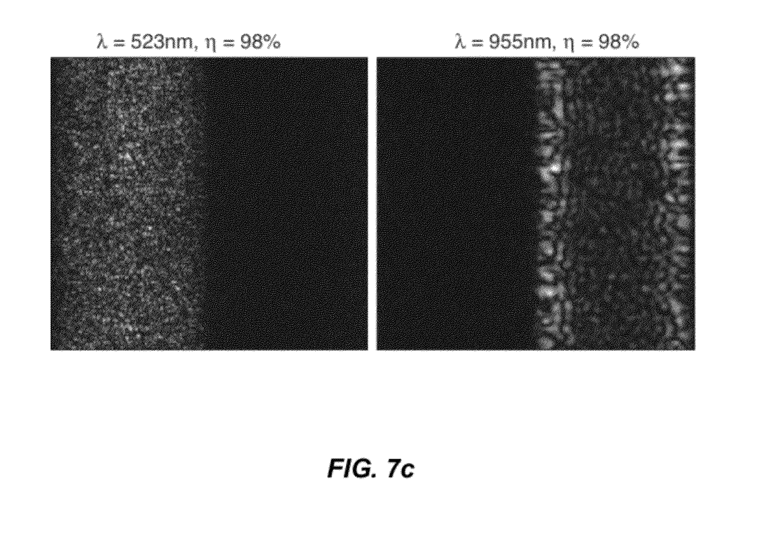

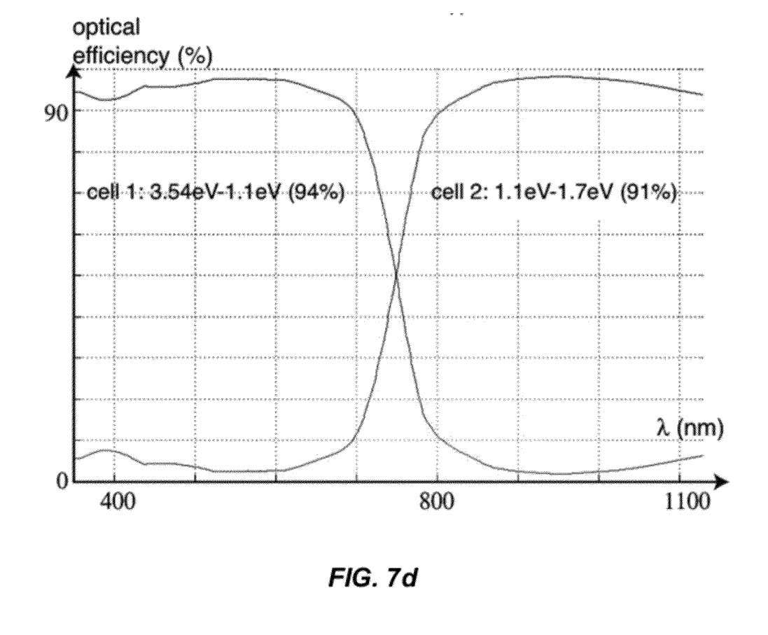

IPPM can also be used to design a one-dimensional (1D) solar concentrator (or polychromat). This is useful for solar applications since a 1D concentrator does not involve daily tracking. FIG. 7a shows a perspective block diagram of this design. Two solar cells 705a-b (and two spectral bands, 3.54 eV-1.1 eV and 1.1 eV-1.7 eV) are used in this example. FIG. 7b shows the height distribution of the array of cells in the completed diffractive optic design. FIG. 7c shows two image amplitudes when the polychromat is illuminated by two wavelengths, 523 nm (left) and 955 nm (right). These images are representative of what is “seen” by the solar cells. FIG. 7d shows an efficiency plot. It is noted that the average spectral efficiencies are over 90% for the two solar cells shown.

In some examples, changing a height of one pixel may decrease the efficiency of the diffractive optic, but in combination with a change in height of other pixels, the overall efficiency may be increased. For broad spectral sources, the order in which pixels are addressed may be less significant than applications for more specific spectrums. The iterations described can be iteratively repeated for all of the cells in the array a desired number of times, or until efficiency does not improve (or at least does not marginally improve). Although this convergence criteria can vary depending on the desired image quality and the like, in one case an efficiency change of less than 1%, less than 0.5% or in some cases less than 0.1% can be suitable. Use of multiple computing nodes can reduce a computational expense of designing a diffractive optic.

The methods and systems of certain embodiments may be implemented in hardware, software, firmware, or combinations thereof. In one embodiment, the method can be executed by software or firmware that is stored in a memory and that is executed by a suitable instruction execution system. If implemented in hardware, as in an alternative embodiment, the method can be implemented with any suitable technology that is well known in the art.

Also within the scope of an embodiment is the implementation of a program or code that can be stored in a non-transitory machine-readable medium to permit a computer to perform any of the methods described above.

Some of the functional units described in this specification have been labeled as modules, in order to more particularly emphasize their implementation independence. The various modules, engines, tools, or modules discussed herein may be, for example, software, firmware, commands, data files, programs, code, instructions, or the like, and may also include suitable mechanisms. For example, a module may be implemented as a hardware circuit comprising custom VLSI (Very Large Scale Integration) circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more blocks of computer instructions, which may be organized as an object, procedure, or function. Nevertheless, the executables of an identified module need not be physically located together, but may comprise disparate instructions stored in different locations which comprise the module and achieve the stated purpose for the module when joined logically together.

Indeed, a module of executable code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices. The modules may be passive or active, including agents operable to perform desired functions.

While the forgoing examples are illustrative of the principles of the present technology in one or more particular applications, it will be apparent to those of ordinary skill in the art that numerous modifications in form, usage and details of implementation can be made without the exercise of inventive faculty, and without departing from the principles and concepts of the technology. Accordingly, it is not intended that the technology be limited, except as by the claims set forth below.

1. A method of designing a diffractive optic, comprising:
identifying an initial performance metric for the diffractive optic including a substrate;
selecting a test cell from an array of cells on the substrate;
changing a height of the test cell by a predetermined height unit;
computing images using diffraction-based propagation through at least a portion of the array of cells;
determining a wavelength metric for each of the images;
consolidating the wavelength metrics for each of the images into a perturbed performance metric;
comparing the perturbed performance metric to the initial performance metric; and
identifying whether the perturbed performance metric is an improvement over the initial performance metric.

2. A method as in claim 1, further comprising assigning the initial performance metric the value of the perturbed performance metric when the perturbed performance metric is an improvement over the initial performance metric.

3. A method as in claim 1, further comprising discarding perturbed performance metric when the perturbed performance metric is not an improvement over the initial performance metric.

4. A method as in claim 1, further comprising repeating the method for each cell in the portion of the array at least once.

5. A method as in claim 1, further comprising repeating the method for a subset of cells within the array at least once.

6. A method as in claim 1, wherein the computing further comprises producing the images at a plurality of discrete wavelengths.

7. A method as in claim 1, wherein the computing further comprises producing the images using a continuous spectrum and the wavelength metric is an image coherence metric.

8. A method as in claim 1, wherein the portion of the array is at least 80% of the cells.

9. A method as in claim 8, wherein the portion of the array is 100% of the cells.

10. A method as in claim 1, wherein the test cell is selected randomly from the array of cells.

11. A method as in claim 1, wherein the test cell is selected from the array of cells according to a predetermined selection pattern.

12. A method as in claim 1, wherein changing the height of the first cell by the predetermined height unit comprises increasing the height by the predetermined height unit.

13. A method as in claim 1, wherein changing the height of the first cell by the predetermined height unit comprises decreasing the height by the predetermined height unit.

14. A method as in claim 1, wherein the plurality of discrete wavelengths is broadband.

15. A method as in claim 1, wherein the plurality of discrete wavelengths is narrowband.

16. A method as in claim 1, wherein the wavelength metric comprises propagation efficiency of at least one of the images through the array of cells.

17. A method as in claim 1, wherein the wavelength metric comprises image uniformity measured after at least one of the images is propagated through the array of cells.

18. A diffractive optic having a surface profile obtained by a process comprising:
identifying an initial performance metric for the diffractive optic including a substrate;
selecting a test cell from an array of cells on the substrate;
changing a height of the test cell by a predetermined height unit;
computing images using diffraction-based propagation through at least a portion of the array of cells;
determining a wavelength metric for each of the images;
consolidating the wavelength metrics for each of the images into a perturbed performance metric;
comparing the perturbed performance metric to the initial performance metric; and
identifying whether the perturbed performance metric is an improvement over the initial performance metric.

19. A diffractive optic, comprising:
a substrate;
an array of cells distributed on the substrate having a non-linear arrangement of cell heights extending from a surface of the substrate; and
wherein the cell heights comprise preselected cell heights for a substantially optimized performance metric of the diffractive optic across a plurality of discrete wavelengths.

20. A diffractive optic as in claim 19, wherein the diffractive optic is a component of a solar concentrator system.

21. A solar concentrator system as in claim 20, further comprising a plurality of solar cells having different ranges of spectral band efficiencies, the diffractive optic further comprising a plurality of regions each having cell heights arranged for increased efficiency for a different spectral band range, wherein each of the plurality of regions has increased efficiency for a specific spectral band range as compared with the efficiency for a same specific spectral band range at a different region arranged for a different spectral band range.

22. A solar concentrator system as in claim 19, wherein the plurality of regions are aligned with the plurality of solar cells such that a region arranged for a specific spectral band range is aligned with a solar cell designed for the specific spectral band range.

23. A system for designing a diffractive optic, comprising:
a performance module for identifying an initial performance metric for the diffractive optic including a substrate;
a cell selection module for selecting a test cell from an array of cells on the substrate;
a height modification module for modifying a height of the test cell by a predetermined height;
an image propagation module for computing diffraction-based propagation of an image through the array of cells at a plurality of discrete wavelengths;
a measurement module for determining a wavelength metric for each of the images and consolidating the wavelength metrics for each of the images into a perturbed performance metric; and
a comparison module for comparing the perturbed performance metric to the initial performance metric;
wherein the performance module is further adapted to identify whether the perturbed performance metric is an improvement over the initial performance metric and assign the initial performance metric with a value of the perturbed performance metric when the perturbed performance metric is an improvement over the initial performance metric, and wherein operations performed each of the system modules collectively comprise cell processing.

24. A system as in claim 23, further comprising a database on a computer readable storage medium for storing the height of the test cell and the initial performance metric.

25. A system as in claim 23, further comprising a plurality of computing nodes for simultaneously or sequentially processing different test cells.

26. A system as in claim 23, further comprising a repetition module for causing the performance module, the cell selection module, the height modification module, the image propagation module, the measurement module, and the comparison module to operate to process each cell in the array of cells at least once.

27. A system as in claim 23, further comprising:
a cell block module for dividing the array of cells into overlapping blocks containing subsets of the cells in the array, wherein multiple overlapping blocks are processed simultaneously; and
a stitching module for stitching the blocks together to reform the array of cells after each cell in the array of cells is processed.
